(19) United States
(12) Patent Application Publication
(10) Pub. No.: US 2011/0297208 A1
(43) Pub. Date: Dec. 8, 2011

(54) METHOD FOR THE PRODUCTION OF A SOLAR PANEL AND SEMI-PRODUCT

(75) Inventors: Jan BAKKER, Bleskensgraaf (NL); Abraham Jan VERSCHOOR, Wijngaarden (NL); Simon DEN HARTIGH, Oud Alblas (NL)

(73) Assignee: EUROTRON B.V., Bleskensgraaf (NL)

(21) Appl. No.: 12/795,053

(22) Filed: Jun. 7, 2010

(51) Int. Cl. H01L 31/0203; H01L 31/18

(52) U.S. Cl. 136/251; 438/66; 257/E31.117

(57) ABSTRACT

A method for the production of a solar panel with plural solar cells, includes steps of:
providing a package, respectively including a backing foil with a pattern of electrically conductive wires and provided with a thermally activated adhesive, a lower layer of fusible foil, such as ethylene vinyl acetate (EVA), applied to the side of the layer of the backing foil to which the adhesive is applied, an array of solar cells, the contacts of which are connected to or can be connected to the electrically conductive wires on the backing foil, an upper layer of fusible foil, such as EVA, provided upon the array of solar cells, and a translucent panel,
placing the package in an auxiliary heating station,
heating the package in the auxiliary heating station so that the package is fixated,
the subsequent transfer of the fixated package to a primary heating station.

The invention relates to the production of solar panels which comprise an array of jointly connected solar cells. Such solar cells or photovoltaic cells are optoelectronic devices by means of which radiation can be converted into electrical current. The cells generally consist of crystalline silicon and are jointly connected by an electrical circuit. That electrical circuit is connected to the contacts of each solar cell. An embodiment is known wherein those contacts are arranged on the front side of the solar cell. In such an embodiment, the electrical circuit, for example in the form of electrically conductive strips of material, is arranged on the front side of the solar panel. A drawback of that embodiment is that a portion of the surface of the panel is occupied by the electrical circuit and therefore cannot be used for the photovoltaic conversion.

Further to this, solar cells are known wherein the contacts are arranged on the back side. The electrical circuit is therefore also arranged on the back side, so that a larger portion of the available surface of the solar panel remains available for the photovoltaic conversion.

Solar panels of these types can be produced in various ways. It is known from U.S. Pat. No. 5,972,732 that a solar panel can be formed consecutively from a layer of foil, an electrically conductive layer, an array of solar cells, followed again by a layer of foil and finally a sturdy light translucent panel, such as a glass panel. Such a package is heated in a kiln, thereby curing the layer of foil, which usually consists of ethylene vinyl acetate.

Before the solar panel is ready after heating and curing the foil layers, however, the various components thereof are arranged in a package in a relatively loosely stacked position with respect to one another. In this state, the package needs to be treated very carefully since relative displacement of the components may otherwise occur. If the various components are dislocated, however, the end-product will be faulty, thus resulting in the malfunction of the electrical contacts. It is also inevitable that the package is subjected to certain displacements during transport, as it is transferred from the assembly station to a kiln for the final production of the solar panel.

The object of the invention is therefore to provide a method for the production of solar panels as referred to in the foregoing, wherein the risk of dislocation of the different components in a package is prevented. This object is achieved by a method for the production of a solar panel with a plurality of solar cells, comprising the steps of:
providing a package, respectively comprising a backing foil with a pattern of electrically conductive wires and which is provided with a thermally activated adhesive, a lower layer of fusible foil, such as ethylene vinyl acetate (EVA), provided on the lower side of the layer of foil to which the adhesive layer is applied, an array of solar cells, the contacts of which are connected to or which can be connected to the electrically conductive wires on the backing foil, an upper layer of fusible foil provided on top of the array of solar cells, such as EVA, and a light translucent panel,
placing the package in an auxiliary heating station
heating the package in an auxiliary heating station so that the package is fixated;
the subsequent transfer of the fixated package to a primary heating station.

In the method according to the invention, the various components from the package that must be formed to compose the solar panel are fixated at an early stage with respect to one another by heating at a moderately high temperature. This fixation process may take place, for example, on the workbench where the package is assembled. The package thus fixated can then be finished, without the risk of displacement of the various components with respect to one another, in a kiln or laminator, whereupon the finished solar panel is obtained. The temperature at which the package is fixated is for example approx. 120° C., whereas the temperature at which the package is formed to produce a finished solar panel is, for example, approx. 150° C. In particular, the fixation of the package in the auxiliary heating station can be performed under atmospheric pressure or ambient pressure.

The method according to the invention can be applied to the production of different types of solar panels. Specifically, but not exclusively, the method can be applied to the production of a solar panel wherein the contacts of the individual solar cells are arranged on the back side thereof, so that a relatively large photovoltaic surface is obtained. In that case the method according to the invention comprises the steps of:
providing a layer of EVA with holes on the foil,
providing quantities of electrically conductive adhesive to the backing foil,
applying the EVA layer in such a manner that the holes coincide with the quantities of adhesive material applied to the backing foil,
the electrical connection of the contacts provided on the solar cells with the electrically conductive wires on the foil via the quantities of electrically conductive adhesive applied in the holes in the layer of EVA.

The electrical connection between the contacts of the individual solar cells and the electrically conductive foil is now established by the electrically conductive adhesive layer in the holes of the EVA layer. However, alternatively, the method may also be applied for the production of solar panels constructed in the traditional manner, whereby the contacts of the solar cells are attached to electrically conductive strips by soldering means. These strips may be applied either on the back side or the front side of the solar cells.

The invention further relates to a semi-product for use in the method as described in the foregoing, respectively comprising a backing foil with a pattern of electrically conductive wires and which is provided with a thermally activated adhesive, a fusible foil, such as ethylene vinyl acetate (EVA), provided on the side of the layer of foil to which the adhesive layer is applied, an array of solar cells, a layer of fusible foil, such as EVA, and a translucent panel, wherein the semi-product has been subjected to an increased temperature at atmospheric pressure.

According to a first embodiment, the thermally activated adhesive layer can be electrically conductive. The EVA layer bordering on said adhesive layer has holes, while the electrical contacts formed on the solar cells are connected via the holes with the electrically conductive adhesive layer and the foil. Alternatively, the contacts of the solar cells can be soldered to the electrically conductive strips. According to a first optional embodiment, in this case the contacts of the solar cells and the electrically conductive strips may be arranged on the front side of the solar cells. According to a second optional embodiment, the contacts of the solar cells and the electrically conductive strips may be arranged on the back side of the solar cells.

The invention will now be described in more detail with reference to the exemplary embodiment shown in the figures.

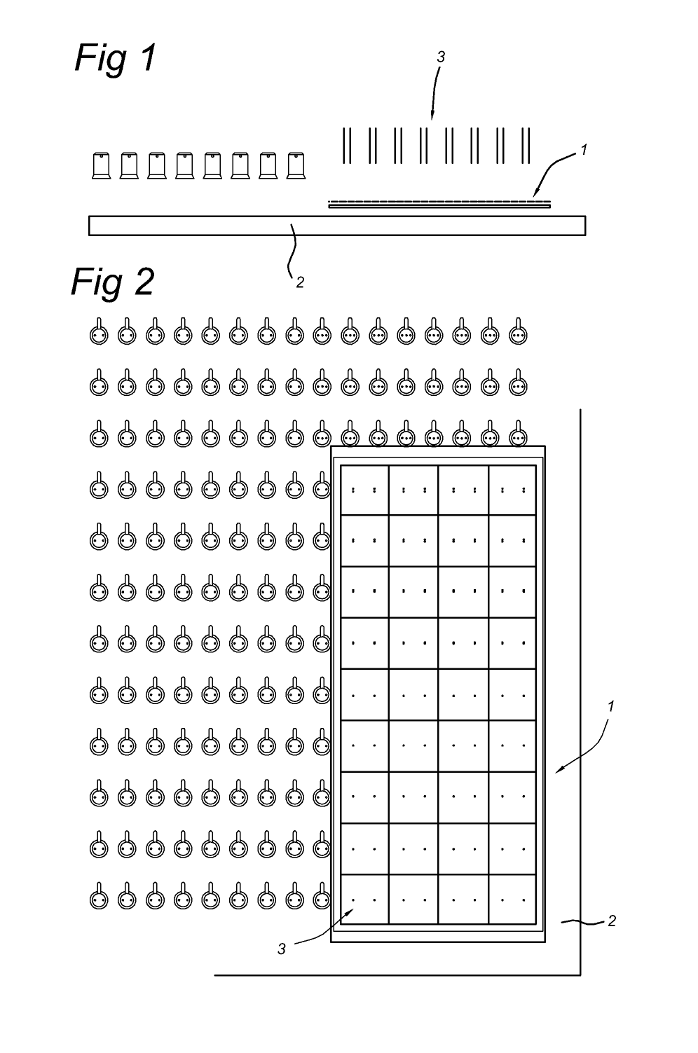

FIG. 1 shows a side view of an arrangement for implementing the method according to the invention.

FIG. 2 shows a top view.

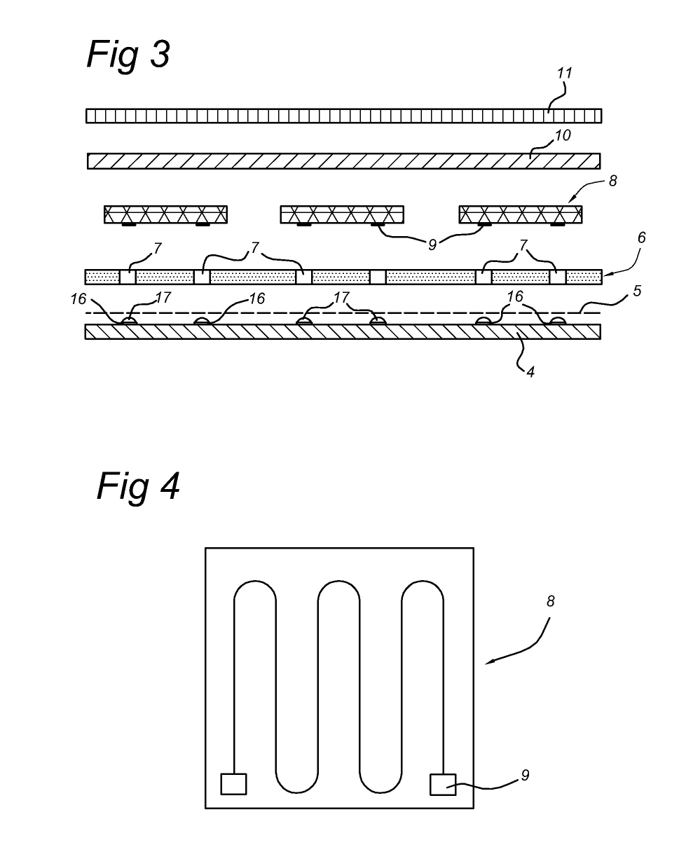

FIG. 3 shows an exploded cross-sectional view through a package for use in the arrangement shown in FIGS. 1 and 2.

FIG. 4 shows a bottom view of a solar panel.

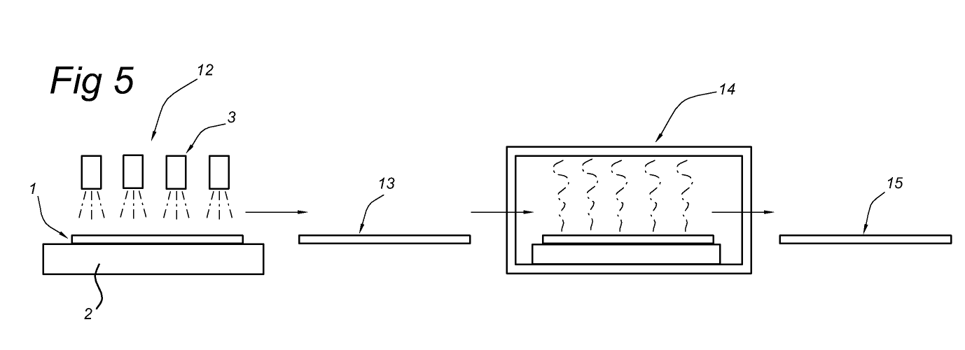

FIG. 5 shows the various steps of the method according to the invention.

The arrangement depicted in FIGS. 1 and 2 shows a package 1, the arrangement of which will be described in more detail with reference to FIG. 3. This package is placed on a workbench 2. A battery of heating equipment 3 is arranged above the package.

As shown in FIG. 3, the package comprises, from bottom to top, a backing foil 4 applied to the back side, upon which a pattern of electrically conductive wires 16 is applied. Adhesive points or adhesive dots 17 are applied to the electrically conductive wires 16. A layer of ethylene vinyl acetate 6 then follows, provided with holes 7. An adhesive point or adhesive dot comprising electrically conductive adhesive material 17 is very precisely applied in and around the holes 7. This electrically conductive adhesive can be a quick-setting silver-based adhesive, or a soldering paste.

An array of solar cells 8 with electrical contacts 9 (see also FIG. 4) on the lower side is arranged on top of the ethylene vinyl acetate 6, each of which are aligned with respect to a hole 7 in the layer 6. A further layer of ethylene vinyl acetate 10 is applied on top of the solar cells 8, whilst the uppermost layer is formed by a glass panel.

In the arrangement shown in the FIGS. 1 and 2, these various components are laid on top of one another so that there are no openings or gaps in between. In this state, the package 1 is heated to 120° C., for example, so that the electrically conductive and thermally activated adhesive 17 is activated. This causes adhesion in the package, while the electrical contacts 9 are brought conductively into contact with the electrically conductive wires 16 on the backing foil 4. An ambient pressure or atmospheric pressure preferably prevails in the auxiliary heating station where this fixation process is carried out.

Upon cooling, the package 1 is fixated in such a manner that a semi-product 13 is formed and this can then be transported without the risk of relative dislocation of the various components occurring. The semi-product 13 can be transferred to a kiln, for example, in order to cure the layers of ethylene vinyl acetate 6, 10 and to produce a finished solar panel 15. This curing process may take place in the usual manner under overpressure.

FIG. 5 is a schematic representation of the process of the method according to the invention. In the heating station 12, the package 1 is fixated on the workbench 2 under the effects of heat originating from the battery of heating equipment 3, for example to a temperature of 120° C. A period of less than a second up to several tens of seconds is sufficient to achieve the desired degree of fixation. The semi-product 13 thus obtained, the components of which are firmly fixated to prevent dislocation, is then fed into the kiln 14 without any difficulty.

A semi-product 13 is then heated further in the kiln 14 to a temperature of 150° C., for example, and then subjected to an overpressure. After some time, whilst maintaining heating and overpressure, for example between 5-7 minutes, the adhesion between the different parts is formed, after which the finished solar panel 15 is obtained.

### LIST OF REFERENCE NUMERALS

1. Package
2. Mold table/bench
3. Battery of heating equipment
4. Backing foil
6. Lower layer of ethylene vinyl acetate
7. Hole in layer
8. Solar cell
9. Solar cell contact
10. Upper layer of ethylene vinyl acetate
11. Glass panel
12. Heating station
13. Semi-product
14. Kiln
15. Solar panel
16. Electrically conductive wire
17. Electrically conductive adhesive material

1. Method for the production of a solar panel (15) with a plurality of solar cells (8), comprising the steps of:
providing a package (1), respectively comprising a backing foil (4) with a pattern of electrically conductive wires (16) and which is provided with a thermally activated adhesive (17), a lower layer of fusible foil, such as ethylene vinyl acetate (EVA) (6), provided on the side of the layer of the backing foil to which the adhesive (17) is applied, an array of solar cells (8), the contacts (9) of which are connected to or can be connected to the electrically conductive wires (16) on the backing foil (4), an upper layer of fusible foil, such as EVA (10), provided on the array of solar cells (8), and a translucent panel (11),
placing the package (1) in an auxiliary heating station (12),
heating the package (1) in an auxiliary heating station (12) so that the package (1) is fixated,
the subsequent transfer of the fixated package (13) to a primary heating station (14).

2. Method according to claim 1, comprising the steps of:
heating the fixated package (13) in the primary heating station (14), and subjecting said fixated package (13) to an overpressure,
cooling the package (13) and the relief of the overpressure for forming a solar panel,
removing the finished solar panel (15) from the primary heating station (14).

3. Method according to claim 1, comprising the step of:
cooling the fixated package (13) after removal thereof from the auxiliary heating station (12).

4. Method according to claim 1, wherein said package is heated in the auxiliary heating station (12) for a period of less than a second up to several tens of seconds.

5. Method according to claim 1, wherein said package is heated in the primary heating station (14) for a period of several minutes, for example 5-7 minutes.

6. Method according to claim 1, comprising the steps of:
providing a layer of EVA (6) with holes (7) on the backing foil (4),
applying quantities of electrically conductive adhesive material (17) to the backing foil (4),
applying the EVA layer (6) in such a manner that the holes (7) coincide with the quantities of adhesive material on the backing foil (4),
forming the electrical connection of the contacts (9) provided on the solar cells (8) with the electrically conductive wires (16) on the backing foil (4) via the quantities of electrically conductive adhesive (17) applied in the holes (7) in the layer of EVA.

7. Method according to claim 6, comprising the step of providing contacts and the electrically conductive strips soldered thereto to the back side of the solar cells.

8. Method according to claim 6, comprising the step of providing contacts and the electrically conductive strips soldered thereto to the front side of the solar cells.

9. Method according to claim 1, comprising the step of:
heating of the package (1) in the auxiliary heating station (12) under atmospheric pressure or ambient pressure.

10. Semi-product (13) for use in the method as described in the foregoing, respectively comprising a backing foil (4) with a pattern of electrically conductive wires (16) and which is provided with a thermally activated adhesive (17), a layer of fusible foil, such as ethylene vinyl acetate (EVA) (6), provided on the side of the layer of foil to which the adhesive (17) is applied, an array of solar cells (8), a layer of fusible foil, such as EVA (10), and a translucent panel (11), wherein the semi-product (13) has been subjected to an increased temperature under atmospheric pressure.

11. Semi-product according to claim 10, wherein the layer of EVA material (6) bordering on the thermally activated adhesive (17) is provided with holes (7) and the electrical contacts (9) provided on the solar cells (8) via quantities of adhesive material applied in the holes are connected with the electrically conductive wires (16) on the backing foil (4).

12. Semi-product according to claim 10, wherein the contacts of the solar cells are soldered to the electrically conductive strips.

13. Semi-product according to claim 12, wherein the contacts of the solar cells and the electrically conductive strips are arranged on the front side of the solar cells.

14. Semi-product according to claim 12, wherein the contacts of the solar cells and the electrically conductive strips are arranged on the back side of the solar cells.

15. Method according to claim 2, comprising the step of:
cooling the fixated package (13) after removal thereof from the auxiliary heating station (12).

16. Method according to claim 2, wherein said package is heated in the auxiliary heating station (12) for a period of less than a second up to several tens of seconds.

17. Method according to claim 3, wherein said package is heated in the auxiliary heating station (12) for a period of less than a second up to several tens of seconds.

18. Method according to claim 2, wherein said package is heated in the primary heating station (14) for a period of several minutes, for example 5-7 minutes.

19. Method according to claim 3, wherein said package is heated in the primary heating station (14) for a period of several minutes, for example 5-7 minutes.

20. Method according to claim 4 wherein said package is heated in the primary heating station (14) for a period of several minutes, for example 5-7 minutes.
